(19) United States
(12) Patent Application Publication
(10) Pub. No.: US 2003/0235790 A1
(43) Pub. Date: Dec. 25, 2003

(54) Method for forming opening and application thereof

(75) Inventor: Ching-Yu Chang, Yilan Hsien (TW)

Correspondence Address: J C PATENTS, INC., 4 VENTURE, SUITE 250, IRVINE, CA, 92618, US

(73) Assignee: MACRONIX INTERNATIONAL CO., LTD., HSINCHU (TW)

(21) Appl. No.: 10/065,644

(22) Filed: Nov. 5, 2002

(30) Foreign Application Priority Data
Jun. 25, 2002 (TW) 91113839

(51) Int. Cl. G03F 7/16; G03F 7/20; G03F 7/40; H01L 21/425; H01L 21/302; H01L 21/461

(52) U.S. Cl. 430/313; 430/315; 430/317; 430/319; 430/394; 438/517; 438/689

(57) ABSTRACT

A method for forming an opening is described. A material layer, a patterned protective layer and a photoresist layer are sequentially formed on a substrate. A first exposure step is performed to form a line/space image on the photoresist layer with a first exposure dosage lower than that required for development. A second exposure step is then performed to define a region to be removed in the photoresist layer with a second exposure dosage, while the sum of the first and the second exposure dosages is equal to that required for development. A development step is conducted to remove the photoresist layer in the region to expose a portion of the patterned protective layer and a portion of the material layer. An etching process is then performed to form an opening in the material layer by using the photoresist layer and the patterned protective layer as a mask.

### CROSS REFERENCE TO RELATED APPLICATIONS

This application claims the priority benefit of Taiwan application serial no. 91 113839, filed Jun. 25, 2002.

### BACKGROUND OF INVENTION

1. Field of Invention

The present invention relates to a method for forming an opening and the application thereof. More particularly, the present invention relates to a method using double exposure techniques to form an opening and the application thereof.

2. Description of Related Art

In order to increase the integration of integrated circuits (IC), the dimensions of semiconductor devices have to be reduced, while the key for device miniaturization is no other than the photolithography techniques. In any semiconductor manufacturing process, photolithography processes are performed to define all kinds of patterns, such as the patterns of films or the pattern of doped regions. In accompany with device miniaturization, however, some problems occur in the photolithography process like insufficient resolution and misalignment. Moreover, during the exposure step of a photolithography process, the light intensity on a region to be formed with dense patterns (dense region) is different from that on a region to be formed with an isolated pattern (sparse region) because of the optical proximity effect (OPE).

Therefore, the critical dimensions (CD) of the defined patterns are not uniform over the dense regions and the sparse regions.

To miniaturize the devices and simultaneously prevent CD deviations over the dense regions and the sparse regions, quite a few methods are proposed based on the use of phase shift by the optical proximity effect (OPE). However, the two methods both need to design masks (PSM) or on optical proximity correction (OPC) to improve the resolutions of exposure process. In one kind of phase shift mask, a phase shifter layer is formed alternately over the gaps between opaque patterns to make a phase shift of 180° and thereby cause destructive interference to enhance the resolution. On the other hand, the OPC method forms assistant patterns on the photo mask to compensate the CD deviation caused special patterns on the photo masks, so the fabrication of the photo masks are time-consuming, expensive and difficult. Moreover, it is not easy to debug the patterns on a photo mask after the photo mask is fabricated.

The aforementioned problems also occur in a coding process of a mask programmable read-only memory (Mask ROM). Since the coding windows do not distribute evenly, there must be regions with dense opening patterns (dense regions) and regions with isolated opening patterns (sparse regions) on the photo mask to cause CD deviations of the coding windows, as mentioned above. The CD deviations of the coding windows cause misalignments of the coding implantation, which may results in severe coding errors to lower the reliability of the Mask ROM.

### SUMMARY OF INVENTION

Accordingly, this invention provides a method for forming a small opening having reduced CD deviations without using phase shift mask (PSM) or optical proximity correction (OPC).

This invention also provides a method for fabricating a Mask ROM, which applies the method for forming a small opening of this invention to the coding process for forming small coding windows, so as to prevent CD deviations of the coding windows and thereby solve the misalignment problem.

A method for forming an opening of this invention is described as follows. A material layer, a plurality of strip protective layers and a photoresist layer are sequentially formed on a substrate. A first exposure step is performed to form a line/space image on the photoresist layer with a first exposure dosage lower than that required for development, such as an exposure dosage equal to one half of the latter. In addition, the orientation of the line/space image is different from or perpendicular to that of the strip protective layers. A second exposure step is then performed to define a region to be removed in the photoresist layer with a second exposure dosage that is also lower than that required for development, while the sum of the first and the second exposure dosages is equal to that required for development. A development step is conducted to remove the photoresist layer in the region to expose a portion of the strip protective layers and a portion of the material layer. An etching process is then performed to form an opening in the material layer by using the photoresist layer and the patterned protective layers as a mask.

A method for coding process of a Mask ROM utilizing the above method of this invention is described as follows. A plurality of buried bit lines are formed in a substrate, and then a gate oxide layer is formed on the substrate. A plurality of strip protective layers are formed over the buried bit lines, and then a plurality of wordlines are formed on the substrate perpendicular to the buried bit lines and crossing over the strip protective layers. Thereafter, a photoresist layer is formed on the substrate covering the word lines. A first exposure step is performed to form a line/space image on the photoresist layer with a first exposure dosage lower than that required for development, such as an exposure-dosage equal to one half of the latter. In addition, the orientation of the line/space image is different from or perpendicular to that of the strip protective layer. A second exposure step is then performed to define a plurality of regions to be removed in the photoresist layer with a second exposure dosage that is also lower than that required for development. The sum of the first and the second exposure dosages is equal to that required for development. A development step is conducted to remove the photoresist layer in the regions to expose selected channel regions and a portion of the strip protective layers. An implantation is then performed using the photoresist layer and the strip protective layers as a mask to implant ions into the selected channel regions.

In the method for forming an opening of this invention, the opening is defined by the strip protective layers, the line/space image formed in the first exposure step with a different orientation, and the exposed region in the second exposure step. Since the strip protective layers and the line/space image each can have a constant pitch/size over the dense regions and the sparse regions, the dimensions of the openings can be uniformed.

Moreover, in the method for fabricating a Mask ROM of this invention, the coding window is defined by the strip protective layers, the line/space image formed in the first exposure step with a different orientation, and the exposed region in the second exposure step. Since the strip protective layers and the line/space image each can have a constant pitch/size over the dense regions and the sparse regions, the dimensions of the coding windows can be uniformed.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A˜1H illustrate a process flow of fabricating a Mask ROM according to a first embodiment of this invention in a cross sectional view, wherein the coding process utilizes the method for forming an opening of this invention;

FIG. 2A˜2F illustrate a process flow of forming an opening according to a second embodiment of this invention in a cross sectional view;

FIG. 3 illustrates a top view of the photoresist layer after the first exposure step according to the first embodiment of this invention;

FIG. 4 illustrates a top view of the photoresist layer after the second exposure step according to the first embodiment of this invention;

FIG. 5 illustrates a top view of the photoresist layer after the development step according to the first embodiment of this invention;

FIG. 6 illustrates a top view of the photoresist layer after the first exposure step according to the second embodiment of this invention;

FIG. 7 illustrates a top view of the photoresist layer after the second exposure step according to the second embodiment of this invention; and

FIG. 8 illustrates a top view of the photoresist layer after the development step according to the second embodiment of this invention.

### DETAILED DESCRIPTION

### First Embodiment

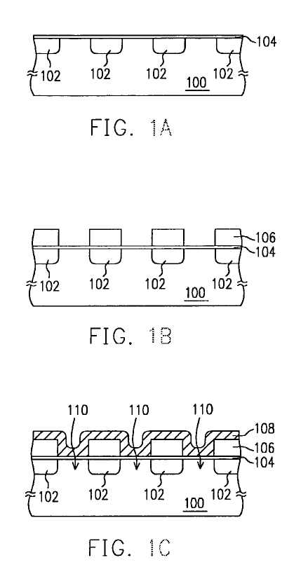

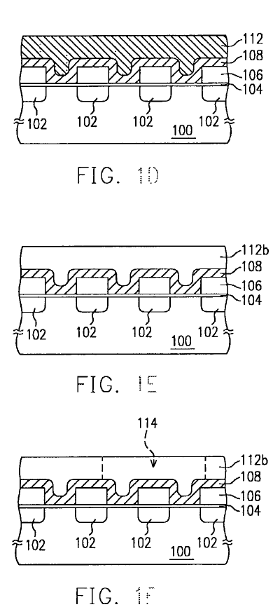

FIG. 1A˜1H illustrate a process flow of fabricating a Mask ROM according to the first embodiment of this invention in a cross sectional view, wherein the coding process utilizes the method for forming an opening of this invention.

Refer to FIG. 1A, a plurality of buried bit lines 102 are formed in a substrate 100. A thermal oxidation process is then conducted to form a gate oxide layer 104 on the substrate 100.

Refer to FIG. 1B, a plurality of strip protective layers 106 are formed over the buried bit lines 102. The strip protective layers 106 comprise a material such as silicon oxide or silicon nitride, and are formed by using chemical vapor deposition (CVD), photolithography and etching techniques.

Refer to FIG. 1C, a word line 108, which comprises a material such as polysilicon, is formed on the substrate 100 perpendicular to the buried bit lines 102 and crossing over the strip protective layers 106. A plurality of channel regions 110 are thus defined in the substrate 100 under the word line 108 and between the buried bit lines 102. Thereafter, a coding process is performed to program the Mask ROM.

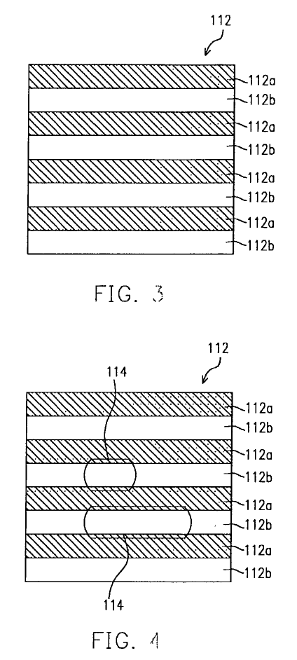

Refer to FIG. 1D, a photoresist layer 112 is formed on the substrate 100 covering the word line 108. The photoresist layer 112 may comprise a positive-type photoresist or a negative-type photoresist suitable for i-line or deep UV photolithography process, while a positive-type photoresist is taken as an example to explain this embodiment. Refer to FIG. 1E and FIG. 3, wherein the latter illustrates a top view of the photoresist layer after the first exposure step according to the first embodiment of this invention. As shown in FIG. 1E and 3, a first exposure step is performed to form a line/space image, which consists of linear patterns 112a and linear spaces 112b arranged alternately, with a first exposure dosage lower than that required for development. The linear patterns 112a correspond to the unexposed regions of the photoresist layer 112 and the linear spaces 112b correspond to the exposed regions. The orientation of the linear patterns/spaces 112a/b is perpendicular to that of the strip protective layers 106, and the first exposure dosage may be one half of that required for development. Moreover, the first exposure step preferably uses off-axis illumination (OAI) to enhance the resolution.

Refer to FIG. 1F and FIG. 4, wherein the latter illustrates a top view of the photoresist layer after the second exposure step according to the first embodiment of this invention. As shown in FIG. 1F and 4, a second exposure step is performed to define a plurality of regions 114 to be removed in the photoresist layer 112 with a second exposure dosage that is also lower than that required for development. In the double exposure step mentioned above, the sum of the first and the second exposure dosages is equal to that required for development, so the regions 114 are the overlaps of the linear spaces 112b and the exposed regions in the second exposure step. Since the first exposure dosage and the second exposure dosage both are lower than that required for development and the sum of the two exposure dosages is equal to the latter, the photoresist layer 112 in the regions 114 can be removed on development. The second exposure dosage may be one half of that required for development, and the second exposure step also preferably uses off-axis illumination (OAI) to enhance the resolution.

Refer to FIG. 1G and 5, wherein the latter illustrates a top view of the photoresist layer after the development step according to the first embodiment of this invention. As shown in FIG. 1G and 5, a development step is conducted to remove the photoresist layer 112 in the regions 114 to form photoresist openings 116 that exposes selected channel regions 110 and a portion of the strip protective layers 106. In this embodiment, each coding window defined by the photoresist layer 112 and the strip protective layers 106 has a rectangle or square shape, of which the dimensions can be reduced to 0.12 μm×0.12 μm with an exposure light of 248 nm.

Refer to FIG. 1H, an ion implantation 120 is performed using the photoresist layer 112 and the strip protective layers 106 as a mask to implant ions into the predetermined channel regions 110 to complete the coding process of the Mask ROM.

As mentioned above, each coding window is defined by the strip protective layers 106, the line/space image 112a/b formed in the first exposure step with a different orientation, and the exposed region in the second exposure step. Since the strip protective layers 106 and the line/space image 112a/b each can have a constant pitch/size over the dense regions and the sparse regions, the dimensions of the coding windows can be uniformed.

### Second Embodiment

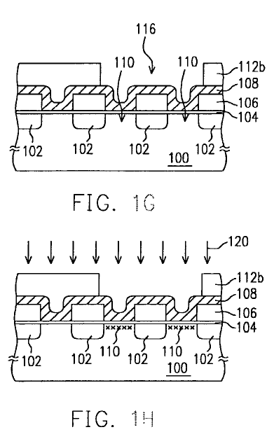

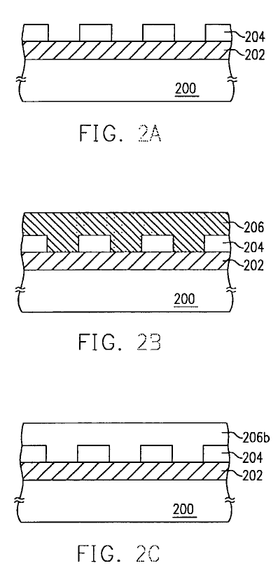

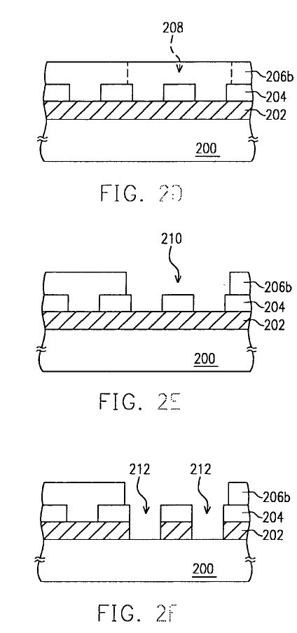

FIG. 2A˜2F illustrate a process flow of forming an opening according to the second embodiment of this invention in a cross sectional view.

Refer to FIG. 2A, a material layer 202 are formed on a substrate 200. A patterned protective layer 204 consisting of, for example, a plurality of strip protective layers, is formed on the material layer 202. The protective layer 204 comprises a material different from that of the material layer 202, such as silicon nitride or silicon oxide.

Refer to FIG. 2B, a photoresist layer 206 is formed on the substrate 200 covering the patterned protective layer 204. The photoresist layer 206 may comprise a positive-type photoresist or a negative-type photoresist suitable for i-line or deep UV photolithography process, while a positive-type photoresist is taken as an example to explain this embodiment.

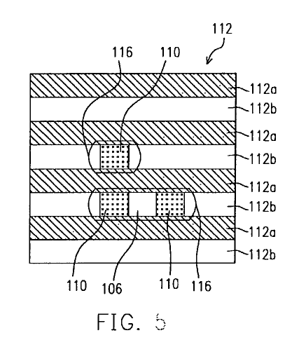

Refer to FIG. 2C and FIG. 6, wherein the latter illustrates a top view of the photoresist layer 206 after the first exposure step according to the second embodiment of this invention. As shown in FIG. 2C and 6, a first exposure step is performed to form a line/space image, which consists of linear patterns 206a and linear spaces 206b arranged alternately, with a first exposure dosage lower than that required for development. The linear patterns 206a correspond to the unexposed regions of the photoresist layer 206 and the linear spaces 206b correspond to the exposed regions. The orientation of the linear patterns/spaces 206a/b is perpendicular to that of the strip protective layers 204, and the first exposure dosage may be one half of that required for development. Moreover, the first exposure step preferably uses off-axis illumination (OAI) to enhance the resolution.

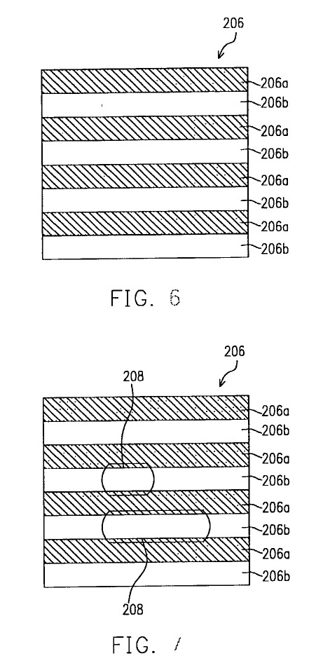

Refer to FIG. 2D and FIG. 7, wherein the latter illustrates a top view of the photoresist layer 206 after the second exposure step according to the present embodiment. As shown in FIG. 2D and 7, a second exposure step is performed to define a plurality of regions 208 to be removed in the photoresist layer 206 with a second exposure dosage that is also lower than that required for development. In the double exposure step mentioned above, the regions 208 are the overlaps of the linear spaces 206b and the exposed regions in the second exposure step. Since the first exposure dosage and the second exposure dosage both are lower than that required for development and the sum of the two is equal to the latter, the photoresist layer 206 in the regions 208 can be removed on development. The second exposure dosage may be one half of that required for development, and the second exposure step also preferably uses off-axis illumination (OAI) to enhance the resolution.

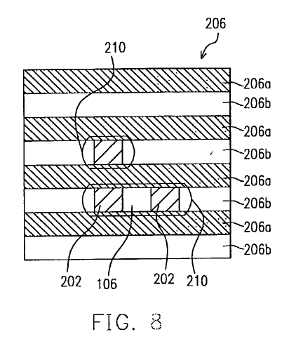

Refer to FIG. 2E and 8, wherein the latter illustrates a top view of the photoresist layer after development according to the present embodiment. As shown in FIG. 2E and 8, a development step is conducted to remove the photoresist layer 206 in the regions 208 to form photoresist openings 210 that exposes a portion of the material layer 202 and a portion of the strip protective layers 204. In this embodiment, each of the regions defined by the photoresist layer 206 and the strip protective layers 204 has a rectangle or square shape.

Refer to FIG. 2F, an etching process is performed using the photoresist layer 206 and the patterned protective layers 204 as a mask to form openings 212 in the material layer 202, wherein the etching rate of the protective layers 204 is lower than that of the material layer 202. Since the patterned protective layer 204 and the line/space image 206a/b each can be formed with a uniform and smaller pitch/size over the dense regions and the sparse regions, the dimensions of an opening can be reduced to 0.12 μm×0.12 μm with an exposure light of 248 nm without using PSM or OPC.

As mentioned above, the openings formed in the material layer are defined by the strip protective layers 204 and the photoresist opening 208 forming by using the double exposure method of this embodiment. Therefore, small and rectangle (or square) openings can be formed in the material layer.

In summary, by using the method for forming opening or the Mask ROM coding method utilizing the former of this invention, the CD deviations of the dense regions and the sparse regions can be avoided without using PSM or OPC. Consequently, the cost and the time for fabricating semiconductor devices can be reduced.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method for forming an opening, comprising:sequentially forming a material layer, a patterned protective layer and a photoresist layer on a substrate;performing a first exposure step to form a line/space image on the photoresist layer with a first exposure dosage lower than a sufficient exposure dosage required for development;performing a second exposure step to define a region to be removed in the photoresist layer with a second exposure dosage lower than the sufficient exposure dosage, while a sum of the first and the second exposure dosages is equal to the sufficient exposure dosage at least;performing a development step to remove the photoresist layer in the region to expose a portion of the patterned protective layer and a portion of the material layer; andperforming an etching process to form an opening in the material layer by using the photoresist layer and the patterned protective layer as a mask.

2. The method of claim 1, wherein the patterned protective layer comprises strip protective layers.

3. The method of claim 2, wherein an orientation of the line/space image is perpendicular to an orientation of the strip protective layers.

4. The method of claim 1, wherein an etching rate of the patterned protective layer is lower than an etching rate of the material layer in the etching process.

5. The method of claim 1, wherein the patterned protective layer comprises silicon nitride or silicon oxide.

6. The method of claim 1, wherein the first exposure dosage is equal to one half of the sufficient exposure dosage.

7. The method of claim 1, wherein the second exposure dosage is equal to one half of the sufficient exposure dosage.

8. The method of claim 1, wherein the first exposure step uses an off-axis illumination.

9. The method of claim 1, wherein the second exposure step uses an off-axis illumination.

10. The method of claim 1, wherein the photoresist layer comprises an i-line photoresist or a deep-UV photoresist.

11. The method of claim 1, wherein the opening has a rectangle or square shape.

12. A method for fabricating a Mask ROM, comprising:forming a plurality of buried bit lines in a substrate;forming a gate dielectric layer on the substrate;forming a plurality of strip protective layers over the buried bit lines;forming a plurality of word lines on the substrate perpendicular to the buried bit lines;forming a photoresist layer on the substrate covering the word lines;performing a first exposure step to form a line/space image on the photoresist layer with a first exposure dosage lower than a sufficient exposure dosage required for development, wherein an orientation of the line/space image is different from an orientation of the strip protective layers; performing a second exposure step to define a plurality of regions to be removed in the photoresist layer with a second exposure dosage that is lower than the sufficient exposure dosage, while a sum of the first and the second exposure dosages is equal to the sufficient exposure dosage at least; performing a development step to remove the photoresist layer in the regions to expose selected channel regions and a portion of the strip protective layers, while a plurality of coding windows are defined by the strip protective layers and the photoresist layer; andimplanting coding ions into the selected channel region with the photoresist layer and the strip protective layers as a mask.

13. The method of claim 12, wherein an orientation of the line/space image is perpendicular to an orientation of the strip protective layers.

14. The method of claim 12, wherein the strip protective layers comprise silicon nitride or silicon oxide.

15. The method of claim 12, wherein the first exposure dosage is equal to one half of the sufficient exposure dosage.

16. The method of claim 12, wherein the second exposure dosage is equal to one half of the sufficient exposure dosage.

17. The method of claim 12, wherein the first exposure step uses an off-axis illumination.

18. The method of claim 12, wherein the second exposure step uses an off-axis illumination.

19. The method of claim 12, wherein the photoresist layer comprises an i-line photoresist or a deep-UV photoresist.

20. The method of claim 12, wherein each coding window has a rectangle or square shape.
